(19) United States
(12) Patent Application Publication
(10) Pub. No.: US 2010/0321979 A1
(43) Pub. Date: Dec. 23, 2010

(54) RESISTANCE CHANGE MEMORY

(76) Inventors: Nobuaki YASUTAKE, Yokohama-shi (JP); Takeshi SONEHARA, Kawasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/816,815

(22) Filed: Jun. 16, 2010

(30) Foreign Application Priority Data
Jun. 18, 2009 (JP) 2009-145473

(51) Int. Cl. G11C 11/00; H01L 45/00; H01L 21/02

(52) U.S. Cl. 365/148; 257/4; 438/382; 257/E45.001; 257/E21.004

(57) ABSTRACT

A resistance change memory includes a first conductive line extending in a first direction, a second conductive line extending in a second direction which is crossed to the first direction, a cell unit including a memory element and a rectification connected in series between the first and second conductive lines, and a control circuit which is connected to both of the first and second conductive lines. The control circuit controls a value of voltage which is applied to the memory element to change a resistance of the memory element reversibly between first and second values. The rectification includes a p-type semiconductor layer, an n-type semiconductor layer and an intrinsic semiconductor layer therebetween. The rectification has a first diffusion prevention area in the intrinsic semiconductor layer.

### CROSS-REFERENCE TO RELATED APPLICATIONS

This application is based upon and claims the benefit of priority from prior Japanese Patent Application No. 2009-145473, filed Jun. 18, 2009, the entire contents of which are incorporated herein by reference.

### BACKGROUND OF THE INVENTION

1. Field of the Invention

The present invention relates to a resistance change memory having a variable resistive element or a phase-change element as a memory element.

2. Description of the Related Art

Recently, resistance change memories such as ReRAM

(Resistive RAM) with a variable resistive element as a memory element and PCRAM (Phase change RAM) with a phase-change element as a memory element are attracting attention as a next-generation nonvolatile semiconductor memory.

Several features of the resistance change memories include (1) a memory cell array of a cross-point type, (2) a large memory capacity realized by three-dimensional integration, and (3) DRAM-like high-speed operation.

When the resistance change memory is put to practical use, for example, the NAND flash memory as a file memory and DRAM as a work memory can be replaced by the resistance change memory.

However, there are many problems to be solved in putting the resistance change memory to practical use. One of the problems is a characteristic and a thickness of a rectification included the cross-point type memory cell array.

In the cross-point type memory cell array, the memory element and the rectification are connected in series between a word line and a bit line.

In the characteristic of the rectification, a large current during application of a forward bias, a small current during application of a reverse bias, and a large breakdown voltage have been improved in order to correctly perform the set/reset operation and the read operation.

In order to satisfy the requirements, the rectification comprises a p-i-n diode (for example, see Jpn. Pat. Appln. KOKAI Publication No. 2008-287827).

In case the thickness of the p-i-n diode as a rectification increases, an aspect ratio of a trench formed after the processing of the p-i-n diode becomes large, which is disadvantageous as regards three-dimensional integration of memory cell arrays.

### BRIEF SUMMARY OF THE INVENTION

A resistance change memory according to an aspect of the present invention comprises a first conductive line extending in a first direction, a second conductive line extending in a second direction which is crossed to the first direction, a cell unit including a memory element and a rectification connected in series between the first and second conductive lines, and a control circuit which is connected to both of the first and second conductive lines, wherein the control circuit controls a value of voltage which is applied to the memory element to change a resistance of the memory element reversibly between first and second values, wherein the rectification includes a p-type semiconductor layer, an n-type semiconductor layer and an intrinsic semiconductor layer therebetween, wherein the rectification has a first diffusion prevention area in the intrinsic semiconductor layer.

### BRIEF DESCRIPTION OF THE SEVERAL VIEWS OF THE DRAWING

FIG. 1 illustrates a resistance change memory according to an embodiment of the invention;

FIG. 2 illustrates a cross-point type memory cell array;

FIG. 3 illustrates a cell unit;

FIGS. 4 and 5 illustrate connection relationships between a memory element and a rectification;

FIGS. 6 to 8 illustrate layouts of first and second control circuits;

FIG. 9 illustrates an operation of the resistance change memory;

FIG. 10 illustrates a device structure of a p-i-n diode;

FIG. 11 illustrates a distribution of impurity concentration;

FIG. 12 illustrates a first embodiment;

FIG. 13 illustrates a cross-sectional view along with XIII-XIII in FIG. 12;

FIG. 14 illustrates a distribution of impurity concentration;

FIG. 15 illustrates a second embodiment;

FIG. 16 illustrates a cross-sectional view along with XVI-XVI in FIG. 15;

FIG. 17 illustrates a distribution of impurity concentration;

FIG. 18 illustrates a method of manufacturing a resistance change memory;

FIG. 19 illustrates a cross-sectional view along with XIX-XIX in FIG. 18;

FIG. 20 illustrates a cross-sectional view along with XX-XX in FIG. 18;

FIG. 21 illustrates a method of manufacturing a resistance change memory;

FIG. 22 illustrates a cross-sectional view along with XXII-XXII in FIG. 21; and

FIG. 23 illustrates a cross-sectional view along with XXIII-XXIII in FIG. 21.

### DETAILED DESCRIPTION OF THE INVENTION

A resistance change memory of an aspect of the present invention will be described below in detail with reference to the accompanying drawings.

1. Basic Concept

The present invention is applied to a resistance change memory in which a memory element is a variable resistive element or a phase-change element. The variable resistive element means an element that is made of a material whose resistance value is changed by a voltage, a current, a heat, or the like. The phase-change element means an element that is made of a material whose physical property such as a resistance and a capacitance is changed by a phase change.

The term phase change (phase transition) embraces the following meanings.

A: Metal-semiconductor transition, metal-insulator transition, metal-metal transition, insulator-insulator transition, insulator-semiconductor transition, insulator-metal transition, semiconductor-semiconductor transition, semiconductor-metal transition, and semiconductor-insulator transition

B: Phase change of quantum states (such as metal-superconductor transition)

C: Paramagnetic-ferromagnetic transition, anti ferromagnetic-ferromagnetic transition, ferromagnetic-ferromagnetic transition, ferromagnetic-ferromagnetic transition, and transition of a combination thereof

D: Paraelectric-ferroelectric transition, paraelectric-collector transition, paraelectric-piezoelectric transition, ferroelectric-ferroelectric transition, antiferroelectric-ferroelectric transition, and transition of a combination thereof

E: Transition of a combination of at least two of A to D

Examples of such phase-changing are a transition from a metal, an insulator, semiconductor, a ferroelectric material, a paraelectric material, a collector, a piezoelectric material, a ferromagnetic material, a ferrimagnetic material, a helimagnetic material, a paramagnetic material, or an antiferromagnetic material to a ferroelectric-ferromagnetic material, and a reverse transition thereof.

In accordance with the above definition, a variable resistive element includes a phase-change element. However, in the embodiment, the variable resistive element mainly refers to an element made of a metal oxide, a metal compound, an organic thin film, carbon, carbon nanotube, and the like.

The invention is applied to resistance change memories such as ReRAM with the variable resistive element as the memory element and PCRAM with the phase-change element as the memory element. This is because the resistance change memories have a cross-point type memory cell array in which a DRAM-like high-speed operation can be performed, while a large memory capacity is realized by three-dimensional integration.

In a cross-point type memory cell array, the memory element and the rectification are connected in series between the word line and the bit line in order to pass a current only through the selected memory element.

Examples of methods for changing a resistance value of the memory element include a method in which the resistance value of the memory element is reversibly changed between at least a first value and a second value by changing a polarity of a voltage applied to the memory element, and a method in which the resistance value of the memory element is reversibly changed between at least a first value and a second value by controlling the magnitude and time of a voltage applied to the memory element without changing the polarity of the voltage.

The former is called a bipolar operation, and the latter is called a unipolar operation.

In the resistance change memory operating by the bipolar operation, it is preferable that the forward bias characteristics and the reverse bias characteristics of the rectification approximate to a line-symmetry to a current axis of I-V characteristics as an axis of symmetry. Therefore, A diode with a MIM structure or a SIS structure, or a transistor with a bipolar transistor structure is used as the rectification.

For example, the bipolar operation is adopted in memories, such as a magnetic random access memory, in which a bi-directional current is required in writing the data. The bipolar operation can be performed by the resistance change memory of the invention.

The resistance change memory of the invention will be described using the unipolar operation in which the resistance value of the memory element is reversibly changed between at least the first value and the second value by controlling the magnitude and time of the voltage applied to the memory element without changing the polarity of the voltage.

A large current during the application of the forward bias, a small current during the application of the reverse bias, and a large breakdown voltage are required as characteristics of a rectification in order to correctly perform the set/reset operation and the read operation, when the unipolar operation is performed by the resistance change memory (hereinafter referred to as cross-point type resistance change memory) comprising the cross-point type memory cell array.

At this point, the case in which the rectification is formed by the p-i-n diode will be studied.

The p-i-n diode comprises an intrinsic semiconductor layer between a p-type semiconductor layer (anode layer) and an n-type semiconductor layer (cathode layer).

The intrinsic semiconductor layer is defined as a semiconductor in which conduction electron density is equal to hole density, ideally a semiconductor that contains no impurity. It is assumed that a semiconductor is dealt with as the intrinsic semiconductor layer when an impurity concentration is considered to be much lower than intrinsic carrier density even if the semiconductor contains a negligible trace of p-type impurity or n-type impurity with respect to intrinsic carrier density.

In order to satisfy the above-described characteristic in the p-i-n diode, it is necessary to particularly thicken the intrinsic semiconductor layer. For example, the intrinsic semiconductor layer is set to a thickness of 100 nm or more.

This is for preventing a change of diode characteristic caused by diffusion of the p-type impurity (such as boron) contained in the p-type semiconductor layer and diffusion of the n-type impurity (such as phosphorous) contained in the n-type semiconductor layer during the wafer process. The thickness of the intrinsic semiconductor layer is determined based on a diffusion length of the p-type impurity and a diffusion length of the n-type impurity.

However, the aspect ratio of the trench formed by processing the p-i-n diode increases with increasing thickness of the p-i-n diode, which disadvantages the three-dimensional integration of the cross-point type memory cell array.

When the resistance change memory that is the next-generation memory is manufactured by a rule of minimum line width of 30 nm or less, generally it is necessary that the thickness of the p-i-n diode (non-ohmic element) be equal to or less than 80 nm in order to realize the three-dimensional integration of the cross-point type memory cell array.

Therefore, in the invention, in order that the thickness of the rectification is adequately thinned while the characteristic of the rectification required for the resistance change memory is satisfied, diffusion prevention areas containing at least one of carbon, nitrogen, fluorine, and oxygen are disposed in an end portion on the intrinsic semiconductor layer side of the p-type semiconductor layer in the p-i-n diode and an end portion on the intrinsic semiconductor layer side of the n-type semiconductor layer.

In the diffusion prevention area, the diffusions of the impurities are prevented because the p-type impurity and the n-type impurity are trapped or reflected by the existence of carbon, nitrogen, fluorine, or oxygen.

However, an atom density of carbon, nitrogen, fluorine, or oxygen contained in the diffusion prevention area is set to 1% or less such that degradation of the diode characteristic is not generated by an increase in resistance value of the diffusion prevention area.

The diffusions of the p-type impurity and n-type impurity are prevented by disposing the diffusion prevention areas in the end portion on the intrinsic semiconductor layer side of the p-type semiconductor layer and the end portion on the intrinsic semiconductor layer side of the n-type semiconductor layer, so that the thickness of the intrinsic semiconductor layer can be thinned within a range of 5 to 80 nm.

As a result, the thickness of the p-i-n diode becomes 80 nm or less.

When the p-i-n diode is used as the rectification of the cross-point type resistance change memory, for example, the thin rectification necessary for the three-dimensional integration of the memory cell array and the maintenance or improvement of the rectifying characteristic can be achieved even in the generation of the minimum line width of 30 nm or less.

2. Embodiments

(1) Overall View

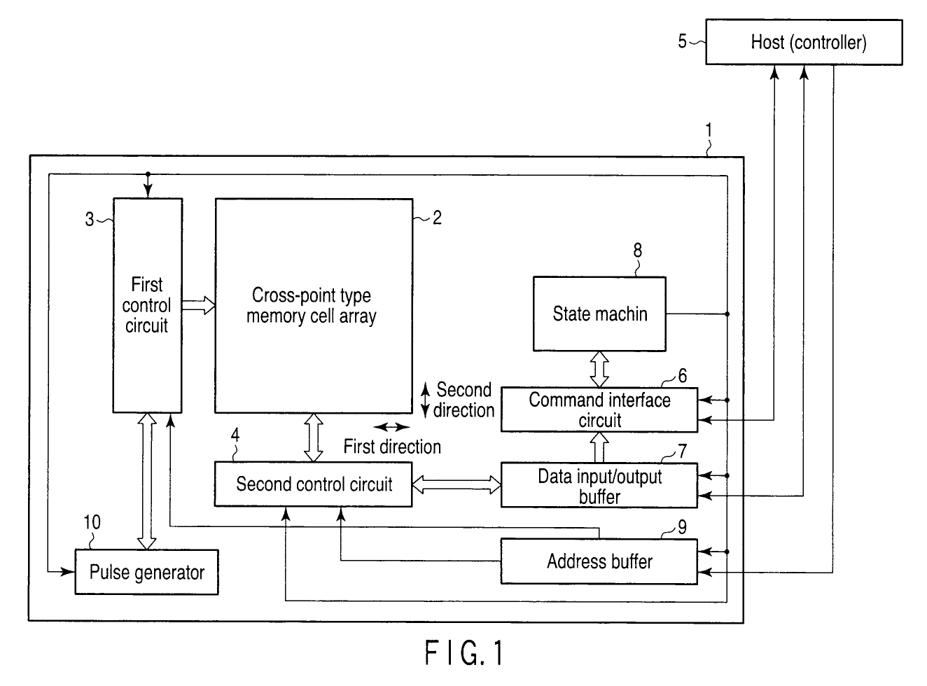

FIG. 1 illustrates a main part of a resistance change memory according to an embodiment of the invention.

Resistance change memory (for example, chip) 1 comprises cross-point type memory cell array 2. Cross-point type memory cell array 2 has a stacked structure of memory cell arrays.

First control circuit 3 is disposed at one end in a first direction of cross-point type memory cell array 2, and second control circuit 4 is disposed at one end in a second direction intersecting the first direction.

For example, first and second control circuits 3 and 4 select one of stacked memory cell arrays based on a memory cell array selection signal.

For example, first control circuit 3 selects a row of cross-point type memory cell array 2 based on a row address signal. For example, second control circuit 4 selects a column of cross-point type memory cell array 2 based on a column address signal.

First and second control circuits 3 and 4 control data write/erasing/read with respect to a memory element in cross-point type memory cell array 2.

First and second control circuits 3 and 4 can perform the data write/erasing/read with respect to one of the stacked memory cell arrays, and can simultaneously perform the data write/erasing/read with respect to at least two or all the stacked memory cell arrays.

As used herein, in resistance change memory 1, the write is referred to as set and the erasing is referred to as reset. It is necessary for a resistance value in the set state to differ from a resistance value in the reset state, and it does not matter whether the resistance value in the set state is higher or lower than the resistance value in the reset state.

A multi-level resistance change memory in which multi-level data is stored in one memory element can be implemented when one of the resistance values is selectively written during the set operation.

Controller (host) 5 supplies a control signal and data to resistance change memory 1. The control signal is fed into command interface circuit 6, and the data is fed into data input/output buffer 7. The controller 5 may be disposed in chip 1, or in a host (computer) that is different from chip 1.

Command interface circuit 6 determines whether the data from host 5 is command data based on the control signal. When the data from host 5 is command data, command interface circuit 6 transfers the data to state machine 8 from data input/output buffer 7.

State machine 8 manages an operation of resistance change memory 1 based on the command data. For example, state machine 8 manages a set/reset operation and a read operation based on the command data from host 5.

Controller 5 can also determine an operation result in resistance change memory 1 by receiving status information managed by state machine 8.

In the set/reset operation and the read operation, controller 5 supplies an address signal to resistance change memory 1. For example, the address signal includes the memory cell array selection signal, the row address signal, and the column address signal.

The address signal is fed into first and second control circuits 3 and 4 through address buffer 9.

In response to a command from state machine 8, pulse generator 10 outputs a voltage pulse or a current pulse necessary for the set/reset operation and the read operation at a predetermined timing.

(2) Memory Cell Array

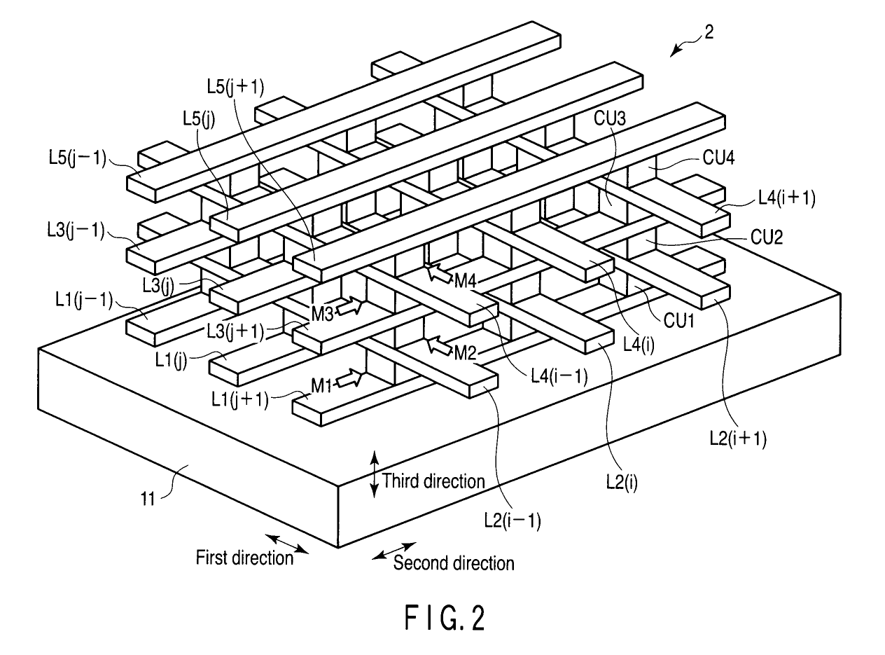

FIG. 2 illustrates a cross-point type memory cell array.

Cross-point type memory cell array 2 is disposed on semiconductor substrate (for example, silicon substrate) 11. A circuit element such as a MOS transistor or an insulating film may be sandwiched between cross-point type memory cell array 2 and semiconductor substrate 11.

In FIG. 2, cross-point type memory cell array 2 comprises four memory cell arrays, M1, M2, M3, and M4 stacked in a third direction (direction perpendicular to a principal surface of semiconductor substrate 11) by way of example, and it is necessary that at least two memory cell arrays be stacked.

Memory cell array M1 comprises cell units CU1 that are arrayed in the first and second directions.

Similarly, memory cell array M2 comprises arrayed cell units CU2, memory cell array M3 comprises arrayed cell units CU3, and memory cell array M4 comprises arrayed cell units CU4.

Each of cell units CU1, CU2, CU3, and CU4 comprises a memory element and a rectification, which are connected in series.

Conductive lines L1(j−1), L1(j), and L1(j+1), conductive lines L2(i−1), L2(i), and L2(i+1), conductive lines L3(j−1), L3(j), and L3(j+1), conductive lines L4(i−1), L4(i), and L4(i+1), and conductive lines L5(j−1), L5(j), and L5(j+1) are disposed on semiconductor substrate 11.

The odd-numbered conductive lines, that is, conductive lines L1(j−1), L1(j), and L1(j+1), conductive lines L3(j−1), L3(j), and L3(j+1), and conductive lines L5(j−1), L5(j), and L5(j+1) are extended toward the second direction from the side of semiconductor substrate 11.

The even-numbered conductive lines, that is, conductive lines L2(i−1), L2(i), and L2(i+1) and conductive lines L4(i−1), L4(i), and L4(i+1) are extended toward the first direction from the side of semiconductor substrate 11.

The conductive lines act as a word line or a bit line.

Lowermost first memory cell array M1 is disposed between first conductive lines L1(j−1), L1(j), and L1(j+1) and second conductive lines L2(i−1), L2(i), and L2(i+1). In the set/reset operation and the read operation to memory cell array Ml, one of conductive lines L1(j−1), L1(j), and L1(j+1) and conductive lines L2(i−1), L2(i), and L2(i+1) acts as the word line, and the other acts as the bit line.

Memory cell array M2 is disposed between second conductive lines L2(i−1), L2(i), and L2(i+1) and third conductive lines L3(j−1), L3(j), and L3(j+1). In the set/reset operation and the read operation to memory cell array M2, one of conductive lines L2(i−1), L2(i), and L2(i+1) and conductive lines L3(j−1), L3(j), and L3(j+1) acts as the word line, and the other acts as the bit line.

Memory cell array M3 is disposed between third conductive lines L3(j−1), L3(j), and L3(j+1) and fourth conductive lines L4(i−1), L4(i), and L4(i+1). In the set/reset operation and the read operation to memory cell array M3, one of conductive lines L3(j−1), L3(j), and L3(j+1) and conductive lines L4(i−1), L4(i), and L4(i+1) acts as the word line, and the other acts as the bit line.

Memory cell array M4 is disposed between fourth conductive lines L4(i−1), L4(i), and L4(i+1) and fifth conductive lines L5(j−1), L5(1), and L5(j+1). In the set/reset operation and the read operation to memory cell array M4, one of the conductive lines L4(i−1), L4(i), and L4(i+1) and conductive lines L5(j−1), L5(j), and L5(j+1) acts as the word line, and the other acts as the bit line.

(3) Cell Unit

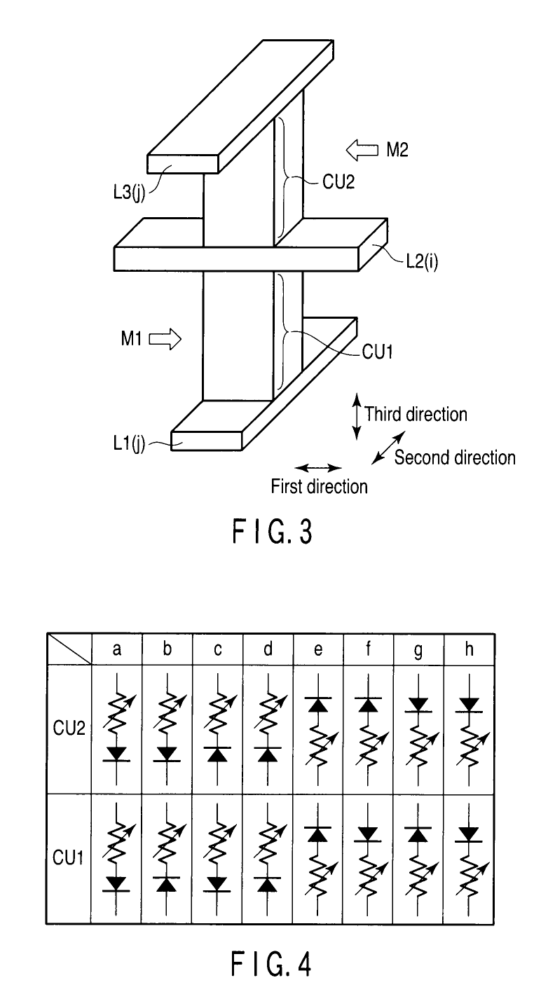

FIG. 3 illustrates a cell unit in two memory cell arrays.

FIG. 3 illustrates, for example, cell units CU1 and CU2 in memory cell arrays M1 and M2 of FIG. 2. At this point, configurations of the cell units in memory cell arrays M3 and M4 of FIG. 2 are similar to those of the cell units of memory cell arrays M1 and M2 of FIG. 2.

Each of cell units CU1 and CU2 comprises the memory element and the rectification, which are connected in series.

There are various patterns in a connection relationship between the memory element and the rectification.

However, it is necessary that the connection relationships between the memory element and the rectification be identical to one another in all the cell units of one memory cell array.

FIGS. 4 and 5 illustrate connection relationships between the memory element and the rectification.

In one cell unit, a total of 4 ways exist in the connection relationship between the memory element and the rectification, that is, 2 ways exist in a positional relationship between the memory element and the rectification and 2 ways exist in an orientation of the rectification. Accordingly, for the cell units of the two memory cell arrays, patterns of 16 ways (4 ways×4 ways) exist in the connection relationship between the memory element and the rectification.

In FIGS. 4 and 5, the letters (a) to (p) designate the connection relationship of 16 ways.

In cell units CU1 and CU2, the lower side of the drawings is the semiconductor substrate side.

Although the embodiment can be applied to all the connection relationship of 16 ways, the connection relationship (c) will mainly be described below by way of example.

This is because that two cell units being adjacent to each other can share a conductive line L as a common word line or a common bit line, when the diodes in the two cell units are arranged symmetrically to the conductive line L. As a result, the operation of the resistance change memory is easily controlled.

(4) Layout of First and Second Control Circuits

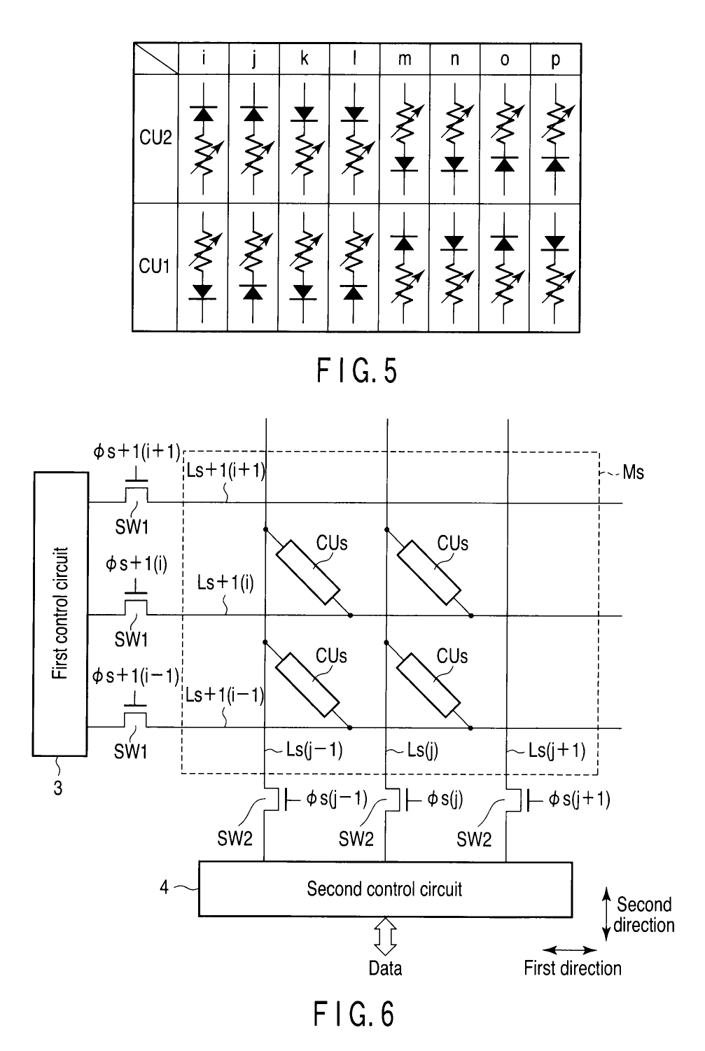

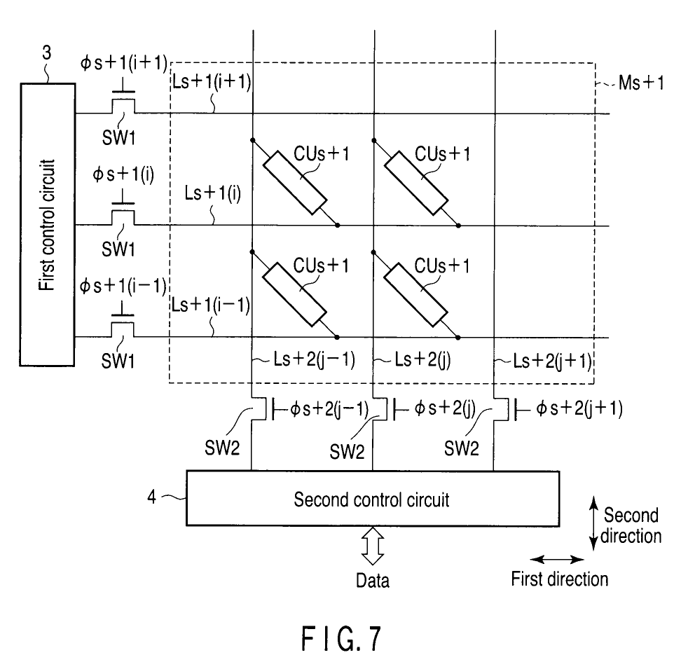

FIGS. 6 and 7 illustrate a first example of a layout of the first and second control circuits.

Memory cell array Ms corresponding to one of the layers of memory cell arrays M1, M2, M3, and M4 of FIG. 2 comprises cell units CUs arrayed as illustrated in FIG. 6. One end of cell unit CUs is connected to conductive lines Ls(j−1), Ls(j), and Ls(j+1), and the other end is connected to conductive lines Ls+1(i−1), Ls+1(i), and Ls+1(i+1).

As illustrated in FIG. 7, memory cell array Ms+1 comprises arrayed cell units CUs+1. One end of cell unit CUs+1 is connected to conductive lines Ls+1(i−1), Ls+1(i), and Ls+1(i+1), and the other end is connected to conductive lines Ls+2(j−1), Ls+2(j), and Ls+2(j+1).

Where s is 1, 3, 5, 7, . . . .

First control circuit 3 is connected to one end in the first direction of each of conductive lines Ls+1(i−1), Ls+1(i), and Ls+1(i+1) through switch element SW1. For example, switch circuit SW1 comprises an N-channel FET (Field Effect Transistor) that is controlled by control signals φ+1(i−1), φ+1(i), and φ+1(i+1).

Second control circuit 4 is connected to one end in the second direction of each of conductive lines Ls(j−1), Ls(j), and Ls(j+1) through switch element SW2. For example, switch circuit SW2 comprises the N-channel FET that is controlled by control signals φs(j−1), φs(j), and φs(j+1).

Second control circuit 4 is connected to one end in the second direction of each of the conductive lines Ls+2(j−1), Ls+2(j), and Ls+2(j+1) through switch element SW2. For example, switch circuit SW2 comprises the N-channel FET that is controlled by control signals φs+2(j−1), φs+2(j), and φs+2(j+1).

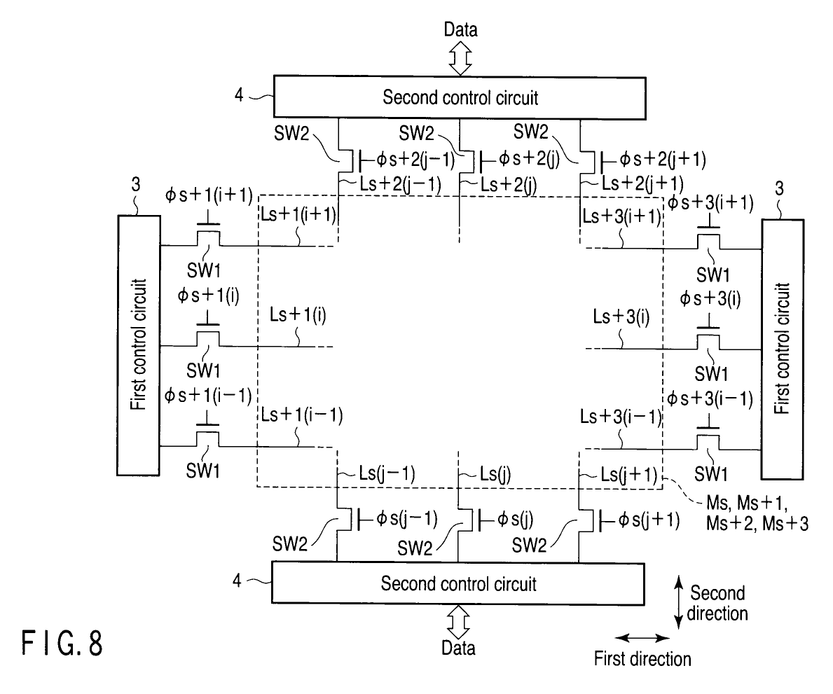

FIG. 8 illustrates a second example of a layout of the first and second control circuits.

The layout of the second example differs from the layout of the first example in that first control circuits 3 are disposed at both ends in the first direction of each of the memory cell arrays Ms, Ms+1, Ms+2, and Ms+3 while second control circuits 4 are disposed at both ends in the second direction of each of the memory cell arrays Ms, Ms+1, Ms+2, and Ms+3.

Where s is 1, 5, 9, 13, . . . .

First control circuits 3 are connected to both ends in the first direction of each of conductive lines Ls+1(i−1), Ls+1(i), and Ls+1(i+1) through switch elements SW1. For example, switch circuit SW1 comprises the N-channel FET that is controlled by control signals φs+1(i−1), φs+1(i), φs+1(i+1), φs+3(i−1), φs+3(i), and φs+3(i+1).

Second control circuits 4 are connected to both ends in the second direction of each of conductive lines Ls(j−1), Ls(j), and Ls(j+1) through switch elements SW2. For example, switch circuit SW2 comprises the N-channel FET that is controlled by control signals φs(j−1), φs(j), φs(j+1), φ+s2(j−1), φs+2(j), and φs+2(j+1).

(5) Operation

An operation of the resistance change memory will be described.

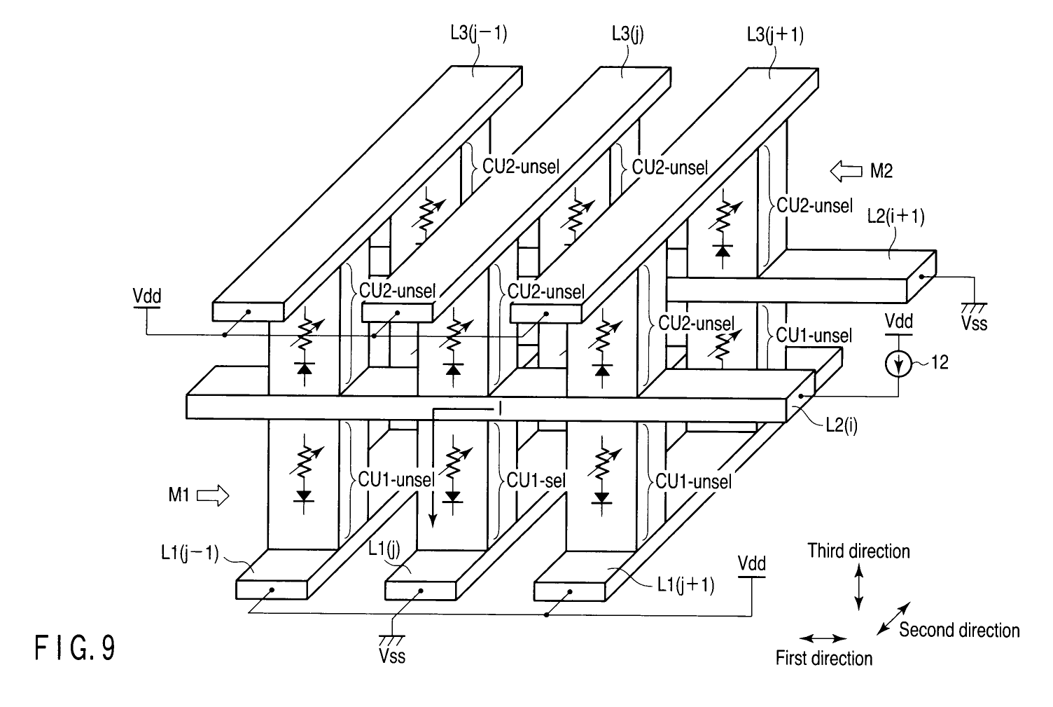

FIG. 9 illustrates two memory cell arrays.

Memory cell array M1 of FIG. 9 corresponds to the memory cell array M1 of FIG. 2, and memory cell array M2 of FIG. 9 corresponds to memory cell array M2 of FIG. 2.

The connection relationship between the memory element and the rectification in cell units CU1 and CU2 corresponds to connection relationship (c) of FIG. 4.

A. Set Operation

A write (set) operation performed to selected cell unit CU1-sel in memory cell array M1 will be described.

An initial state of selected cell unit CU1-sel is an erasing (reset) state.

It is assumed that the reset state is a high-resistance state (100 kΩ to 1 MΩ) while the set state is a low-resistance state (1 KΩ to 10 KΩ).

Selected conductive line L2(i) is connected to high-potential-side power supply potential Vdd, and selected conductive line L1(j) is connected to low-potential-side power supply potential Vss.

In the first conductive lines from the semiconductor substrate side, non-selected conductive lines L1(j−1) and L1(j+1) other than selected conductive line L1(j) are connected to power supply potential Vdd. In the second conductive lines from the semiconductor substrate side, non-selected conductive line L2(i+1) other than selected conductive line L2(i) is connected to power supply potential Vss.

Third non-selected conductive lines L3(j−1), L3(j), and L3(j+1) from the semiconductor substrate side are connected to power supply potential Vdd.

At this point, because the forward bias is applied to the rectification (diode) in selected cell unit CU1-sel, set current I-set is passed from a constant current source to selected cell unit CU1-sel, and the resistance value of the memory element in selected cell unit CU1-sel changes from the high-resistance state to the low-resistance state.

In the set operation, a voltage of 1 to 2 V is applied to the memory element in selected cell unit CU1-sel, and the current density of set current I-set passed through the memory element (high-resistance state) is set to a range of 1×10⁵ to 1×10⁷ A/cm².

On the other hand, in non-selected cell units CU1-unsel in memory cell array M1, the reverse bias is applied to the rectification (diode) in the cell unit, which is connected between non-selected conductive lines L1(j−1) and L1(j+1) and non-selected conductive line L2(i+1).

Similarly, in non-selected cell units CU2-unsel in memory cell array M2, the reverse bias is applied to the rectification (diode) in the cell unit, which is connected between non-selected conductive line L2(i+1) and non-selected conductive lines L3(j−1), L3(j), and L3(j+1).

Accordingly, a sufficiently small current during the application of the reverse bias and sufficiently large breakdown voltage are required for the characteristic of the rectification in the cell unit.

B. Reset Operation

An erasing (reset) operation performed to selected cell unit CU1-sel in memory cell array M1 will be described.

Selected conductive line L2(i) is connected to high-potential-side power supply potential Vdd, and selected conductive line L1(j) is connected to low-potential-side power supply potential Vss.

In first conductive lines from the semiconductor substrate side, non-selected conductive lines L1(j−1) and L1(j+1) other than selected conductive line L1(j) are connected to power supply potential Vdd. In the second conductive lines from the semiconductor substrate side, non-selected conductive line L2(i+1) other than selected conductive line L2(i) is connected to power supply potential Vss.

Third non-selected conductive lines L3(j−1), L3(j), and L3(j+1) from the semiconductor substrate side are connected to power supply potential Vdd.

At this point, because the forward bias is applied to the rectification (diode) in selected cell unit CU1-sel, reset current I-reset is passed from the constant current source to selected cell unit CU1-sel, and the resistance value of the memory element in selected cell unit CU1-sel changes from the low-resistance state to the high-resistance state.

In the reset operation, the voltage of 1 to 3 V is applied to the memory element in selected cell unit CU1-sel, and the current density of reset current I-reset passed through the memory element (low-resistance state) is set to a range of 1×10³ to 1×10⁶ A/cm².

On the other hand, in non-selected cell units CU1-unsel in memory cell array M1, the reverse bias is applied to the rectification (diode) in the cell unit, which is connected between non-selected conductive lines L1(j−1) and L1(j+1) and non-selected conductive line L2(i+1).

Similarly, in non-selected cell units CU2-unsel in memory cell array M2, the reverse bias is applied to the rectification (diode) in the cell unit, which is connected between non-selected conductive line L2(i+1) and non-selected conductive lines L3(j−1), L3(j), and L3(j+1).

Accordingly, a sufficiently small current during the application of the reverse bias and sufficiently large breakdown voltage are required for the characteristic of the rectification in the cell unit.

Set current I-set and reset current I-reset differ from each other. The voltage applied to the memory element in selected cell unit CU1-sel in order to produce set current I-set and reset current I-reset depends on a material for the memory element.

C. Read Operation

A read operation performed to selected cell unit CU1-sel in memory cell array M1 will be described.

Selected conductive line L2(i) is connected to high-potential-side power supply potential Vdd, and selected conductive line L1(j) is connected to low-potential-side power supply potential Vss.

In first conductive lines from the semiconductor substrate side, non-selected conductive lines L1(j−1) and L1(j+1) other than selected conductive line L1(j) are connected to power supply potential Vdd. In the second conductive lines from the semiconductor substrate side, non-selected conductive line L2(i+1) other than selected conductive line L2(i) is connected to power supply potential Vss.

Third non-selected conductive lines L3(j−1), L3(j), and L3(j+1) from the semiconductor substrate side are connected to power supply potential Vdd.

At this point, because the forward bias is applied to the rectification (diode) in selected cell unit CU1-sel, read current I-read is passed from the constant current source to the memory element (high-resistance state or low-resistance state) in selected cell unit CU1-sel.

Accordingly, for example, the data (resistance value) of the memory element can be read by detecting a potential change at a sense node in passing read current I-read through the memory element.

At this point, it is necessary that read current I-read be sufficiently smaller than set current I-set and reset current I-reset such that the resistance value of the memory element does not change during the read operation.

As with the set/reset operation, during the read operation, the reverse bias is applied to the rectification (diode) in the cell unit which is connected between non-selected conductive lines L1(j−1) and L1(j+1) and non-selected conductive line L2(i+1), in non-selected cell units CU1-unsel in memory cell array M1.

Similarly, in non-selected cell units CU2-unsel in memory cell array M2, the reverse bias is applied to the rectification (diode) in the cell unit which is connected between non-selected conductive line L2(i+1) and non-selected conductive lines L3(j−1), L3(j), and L3(j+1).

Accordingly, a sufficiently small current during the application of the reverse bias and sufficiently large breakdown voltage are required for the characteristic of the rectification in the cell unit.

(6) Rectification

The rectification (non-ohmic element) used in the resistance change memory of the invention will be described in detail. It is assumed that the connection relationship (c) of FIG. 2 holds between the memory element and the rectification in the cell unit.

### A. Comparative Example

FIG. 10 illustrates a structure of the p-i-n diode.

Electrode layer 12, n-type semiconductor layer 13, intrinsic semiconductor layer 14, p-type semiconductor layer 15, and electrode layer 16 are stacked on conductive line L2(i) extended in the first direction. Intrinsic semiconductor layer 14 is a semiconductor layer in which the impurity is not doped or a semiconductor layer that contains a negligible trace of impurity with respect to the intrinsic carrier density.

P-i-n diode D-pin comprises n-type semiconductor layer 13, intrinsic semiconductor layer 14, and p-type semiconductor layer 15.

Memory element 17 and electrode layer 18 are stacked on electrode layer 16, and memory element 17 is formed by the variable resistive element or the phase-change element. Conductive line L3(j) extended in the second direction intersecting the first direction is disposed on electrode layer 18.

In p-i-n diode D-pin, the reverse current of the p-i-n diode to which the reverse bias is applied during the set/reset operation be adequately suppressed in order to realize the set/reset operation.

Therefore, the thickness in the third direction of p-i-n diode D-pin is set to the range of 100 nm to 200 nm. For example, the thickness of n-type semiconductor layer 13 is set to 15 nm, the thickness of intrinsic semiconductor layer 14 is set to 120 nm, the thickness of p-type semiconductor layer 15 is set to 15 nm, and the thickness of p-i-n diode D-pin is set to 150 nm.

As illustrated in FIG. 11, intrinsic semiconductor layer 14 is relatively thickened in consideration of the diffusion of the n-type impurity (for example, phosphorous) contained in n-type semiconductor layer 13 and the diffusion of the p-type impurity (for example, boron) contained in p-type semiconductor layer 15.

However, in manufacturing the resistance change memory that is the next-generation memory by the rule of minimum line width of 30 nm or less, while a width of the trench formed after the processing of the rectification becomes 30 nm or less, a height of the trench exceeds 100 nm included the thicknesses of the memory element and electrode layer.

Therefore, the aspect ratio of the trench increases to disadvantage the three-dimensional integration of the cross-point type memory cell array.

Generally, in case the resistance change memory that is the next-generation memory is manufactured by the rule of minimum line width of 30 nm or less, desirably the thickness of the rectification (non-ohmic element) is set to 80 nm or less in order to realize the three-dimensional integration of the cross-point type memory cell array.

### B. First Embodiment

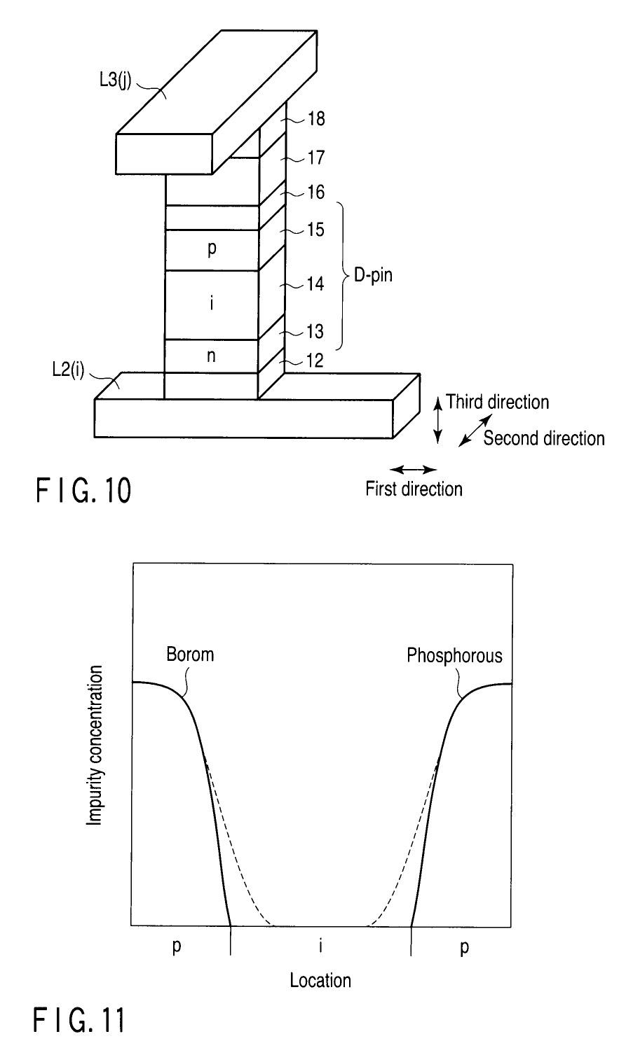

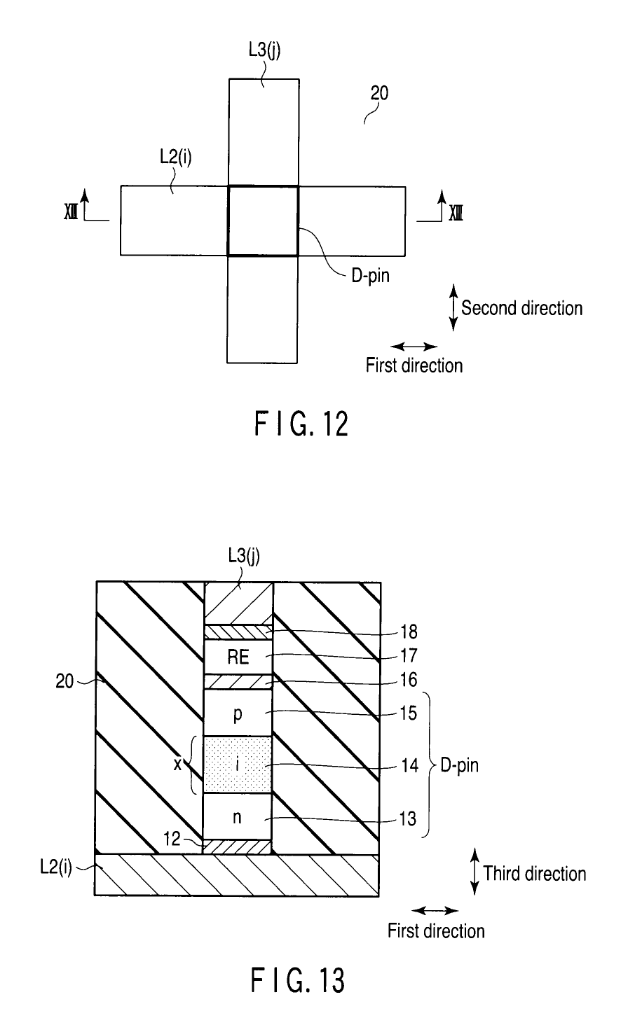

FIG. 12 illustrates a structure of a p-i-n diode according to a first embodiment of the invention as viewed from above. FIG. 13 is a sectional view taken on a line XIII-XIII of FIG. 12.

Electrode layer 12, n-type semiconductor layer 13, intrinsic semiconductor layer 14, p-type semiconductor layer 15, and electrode layer 16 are stacked on conductive line L2(i) extended in the first direction. P-i-n diode D-pin comprises n-type semiconductor layer 13, intrinsic semiconductor layer 14, and p-type semiconductor layer 15.

Memory element (RE) 17 and electrode layer 18 are stacked on electrode layer 16, and memory element 17 is formed of the variable resistive element or the phase-change element. Conductive line L3(j) extended in the second direction intersecting the first direction is disposed on electrode layer 18.

Diffusion prevention areas X containing at least one of carbon, nitrogen, fluorine, and oxygen are disposed in the end portion on the side of intrinsic semiconductor layer 14 of n-type semiconductor layer 13 in p-i-n diode D-pin and the end portion on the side of intrinsic semiconductor layer 14 of p-type semiconductor layer 15.

In the first embodiment, diffusion prevention area X includes the whole of intrinsic semiconductor layer 14.

The concentration of the n-type impurity contained in n-type semiconductor layer 13 is set to 1×10²⁰ atoms/cm³ or more. The concentration of the p-type impurity contained in p-type semiconductor layer 15 is set to 1×10²⁰ atoms/cm³ or more. The reason why the concentration of the impurity is set to 1×10²⁰ atoms/cm³ or more is because the leak current can decrease during the reverse bias while the forward current is gained.

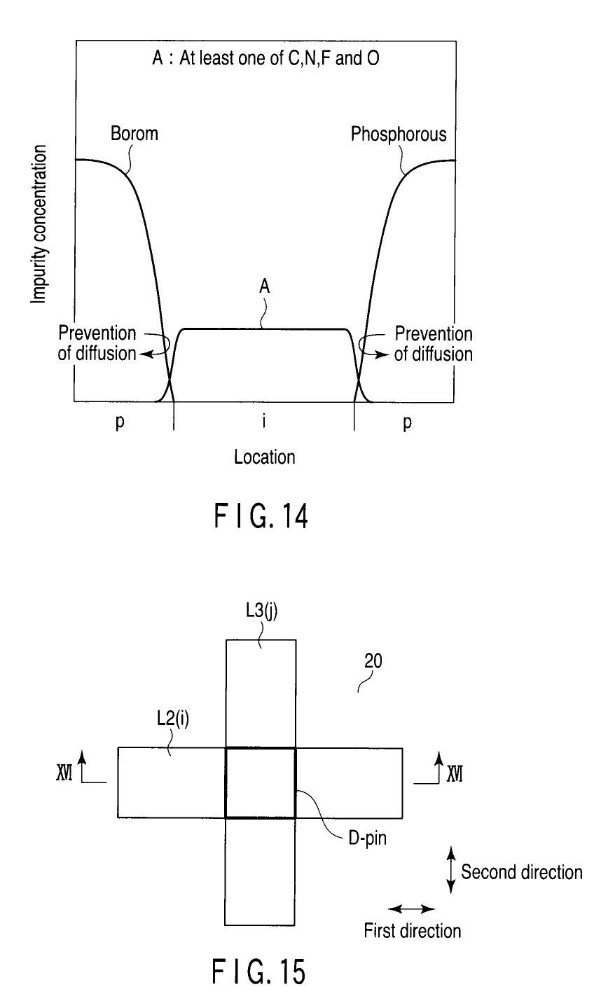

In diffusion prevention area X, as illustrated in FIG. 14, the diffusions of the impurities are prevented because the p-type impurity and the n-type impurity are trapped or reflected by the existence of carbon, nitrogen, fluorine, or oxygen.

However, the atom density of carbon, nitrogen, fluorine, or oxygen contained in the diffusion prevention area is set to 1% or less such that the degradation of the diode characteristic is not generated by the increase in resistance value of diffusion prevention area X.

The diffusions of the p-type impurity and n-type impurity to intrinsic semiconductor layer 14 are prevented by disposing diffusion prevention areas X in the end portion on the side of intrinsic semiconductor layer 14 of n-type semiconductor layer 13 and the end portion on the side of intrinsic semiconductor layer 14 of p-type semiconductor layer 15, so that the thickness of intrinsic semiconductor layer 14 can be thinned within the range of 5 to 80 nm.

One of the features of p-i-n diode D-pin is that the reverse current caused by the reverse bias can be suppressed to an adequately low level during the set/reset operation even if the thickness in the third direction of p-i-n diode D-pin is set to 80 nm or less.

Specifically, the thickness in the third direction of p-i-n diode D-pin is set to the range of 25 nm to 80 nm. For example, the thickness of n-type semiconductor layer 13 is set to 20 nm, the thickness of intrinsic semiconductor layer 14 is set to 5 nm, and the thickness of p-type semiconductor layer 15 is set to 20 nm, whereby the thickness of p-i-n diode D-pin becomes 45 nm.

When the p-i-n diode of the first embodiment is used as the rectification of the cross-point type resistance change memory, for example, the thin rectification and the maintenance or improvement of the rectifying characteristic can be achieved even in the generation of the minimum line width of 30 nm or less.

### C. Second Embodiment

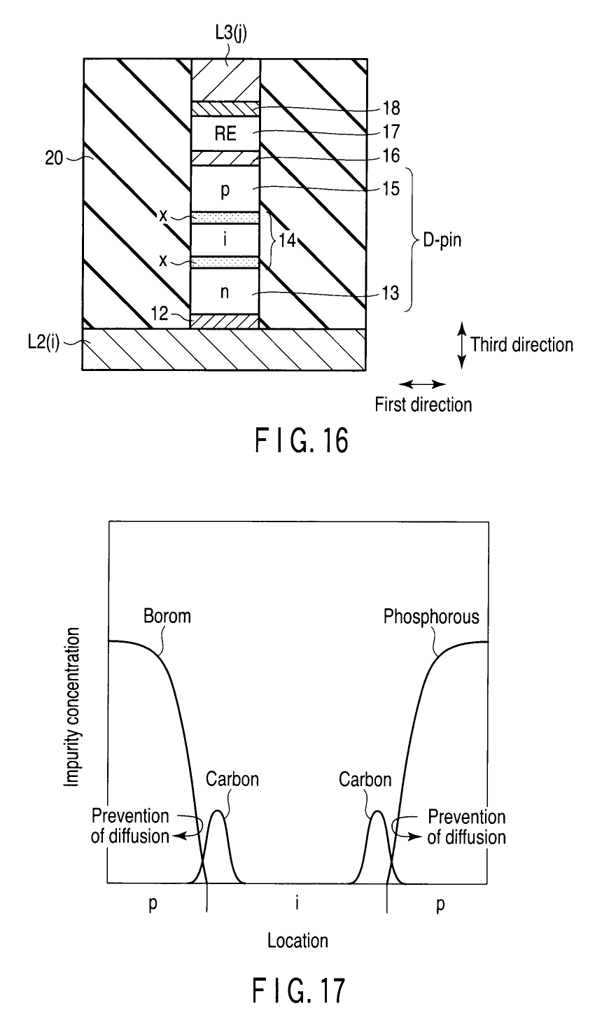

FIG. 15 illustrates a structure of a p-i-n diode according to a second embodiment of the invention as viewed from above. FIG. 16 is a sectional view taken on a line XVI-XVI of FIG. 15.

Electrode layer 12, n-type semiconductor layer 13, intrinsic semiconductor layer 14, p-type semiconductor layer 15, and electrode layer 16 are stacked on conductive line L2(i) extended in the first direction. P-i-n diode D-pin comprises n-type semiconductor layer 13, intrinsic semiconductor layer 14, and p-type semiconductor layer 15.

Memory element (RE) 17 and electrode layer 18 are stacked on electrode layer 16, and memory element 17 is formed by the variable resistive element or the phase-change element. Conductive line L3(j) extended in the second direction intersecting the first direction is disposed on electrode layer 18.

Diffusion prevention areas X containing at least one of carbon, nitrogen, fluorine, and oxygen are disposed in the end portion on the side of intrinsic semiconductor layer 14 of n-type semiconductor layer 13 in p-i-n diode D-pin and the end portion on the side of intrinsic semiconductor layer 14 of p-type semiconductor layer 15.

In the second embodiment, diffusion prevention areas X exist at an interface between n-type semiconductor layer 13 and intrinsic semiconductor layer 14 and an interface between p-type semiconductor layer 15 and intrinsic semiconductor layer 14.

At this point, in diffusion prevention area X, carbon may not be layered in the third direction, carbon may be formed into a dot shape, and carbon may be formed into the dot shape in a plane in the first and second directions. This is because the n-type impurity and the p-type impurity can be trapped or reflected even if diffusion prevention area X is formed into the dot shape.

The concentration of the n-type impurity contained in n-type semiconductor layer 13 is set to 1×10²⁰ atoms/cm³ or more. The concentration of the p-type impurity contained in p-type semiconductor layer 15 is set to 1×10²⁰ atoms/cm³ or more. The reason why the concentration of the impurity is set to 1×10²⁰ atoms/cm³ or more is because the leak current can decrease during the reverse bias while the forward current is gained.

In diffusion prevention area X, as illustrated in FIG. 17, the diffusions of the impurities to the intrinsic semiconductor layer 14 are prevented because the p-type impurity and the n-type impurity are trapped or reflected by the existence of carbon, nitrogen, fluorine, or oxygen.

However, the atom density of carbon, nitrogen, fluorine, or oxygen contained in the diffusion prevention area is set to 1% or less such that the degradation of the diode characteristic is not generated by the increase in resistance value of diffusion prevention area X.

The diffusions of the p-type impurity and n-type impurity to the intrinsic semiconductor layer 14 are prevented by disposing diffusion prevention areas X in the end portion on the side of intrinsic semiconductor layer 14 of n-type semiconductor layer 13 and the end portion on the side of intrinsic semiconductor layer 14 of p-type semiconductor layer 15, so that the thickness of intrinsic semiconductor layer 14 can be thinned within the range of 5 to 80 nm.

One of the features of p-i-n diode D-pin is that the reverse current caused by the reverse bias can be suppressed to an adequately low level during the set/reset operation even if the thickness in the third direction of p-i-n diode D-pin is set to 80 nm or less.

Specifically, the thickness in the third direction of p-i-n diode D-pin is set to the range of 25 nm to 80 nm. For example, the thickness of n-type semiconductor layer 13 is set to 20 nm, the thickness of intrinsic semiconductor layer 14 is set to 5 nm, and the thickness of p-type semiconductor layer 15 is set to 20 nm, whereby the thickness of p-i-n diode D-pin becomes 45 nm.

In case the p-i-n diode of the first embodiment is used as the rectification of the cross-point type resistance change memory, for example, the thin rectification and the maintenance or improvement of the rectifying characteristic can be achieved even in the generation of the minimum line width of 30 nm or less.

(7) Manufacturing Method

A method of manufacturing the p-i-n diode according to the invention will be described.

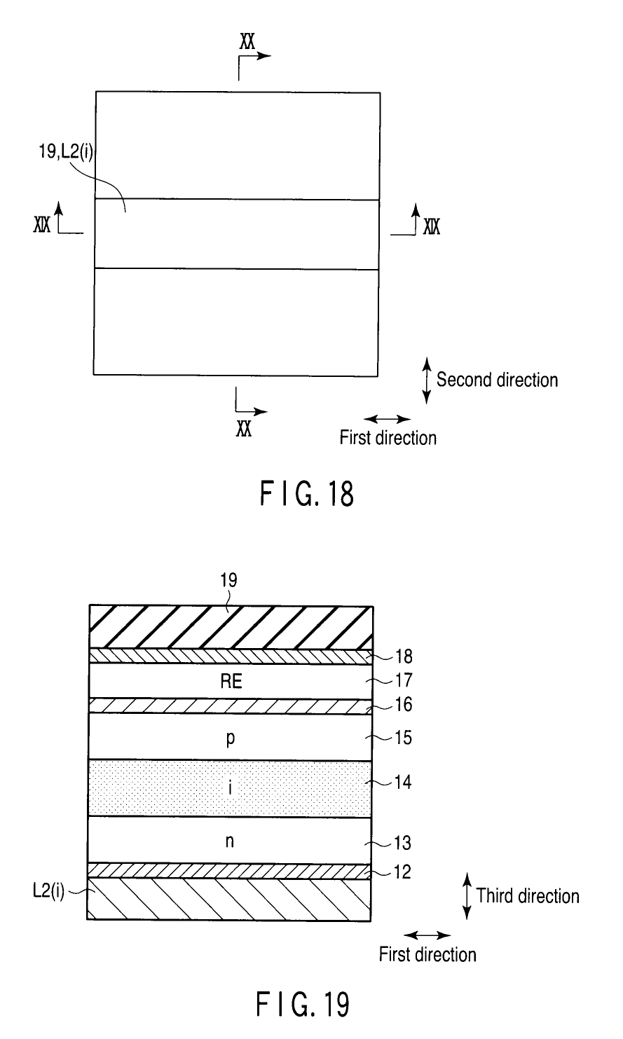

FIGS. 18 and 21 illustrate the structure of the p-i-n diode of the invention as viewed from above.

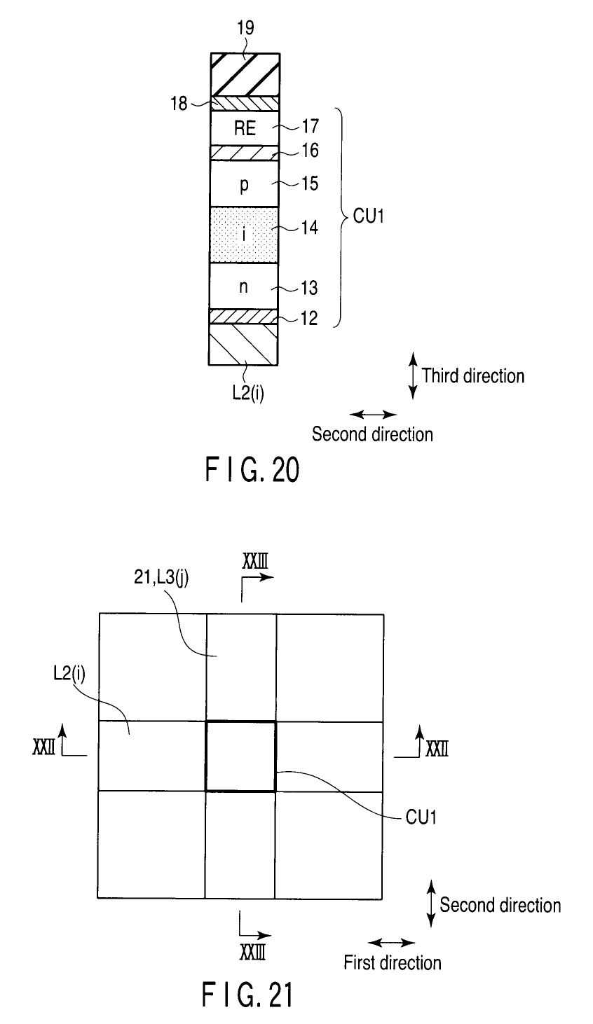

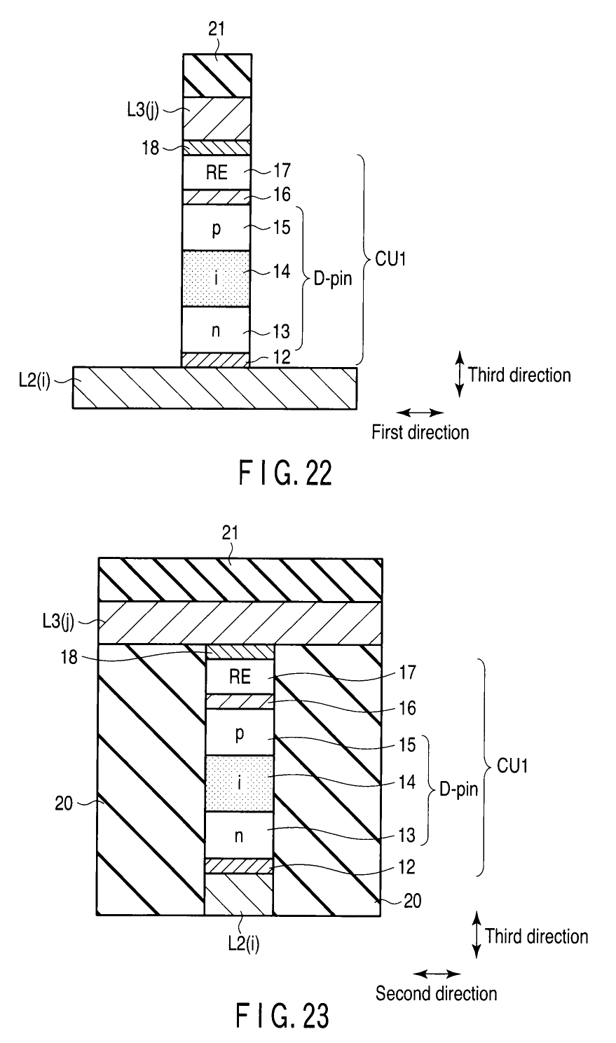

FIGS. 19 and 22 are sectional views taken on a line XIX-XIX of FIGS. 18 and 21, and FIGS. 20 and 23 are sectional views taken on a line XX-XX of FIGS. 18 and 21.

As illustrated in FIGS. 18 to 20, electrode layer 12 is formed on the first conductive layer.

For example, an amorphous epitaxial layer is formed on electrode layer 12 by epitaxial growth.

The amorphous epitaxial layer comprises n-type semiconductor layer 13 in which the n-type impurity is doped, intrinsic semiconductor layer 14 that contains at least one of carbon, nitrogen, fluorine, and oxygen, and p-type semiconductor layer 15 in which the p-type impurity is doped.

N-type semiconductor layer 13, intrinsic semiconductor layer 14 that contains at least one of carbon, nitrogen, fluorine, and oxygen, and p-type semiconductor layer 15 in which the p-type impurity is doped can be manufactured by changing a composition of deposition gas during the deposition.

At this point, because the manufacturing method of FIGS. 18 to 23 corresponds to the structure of the first embodiment, at least one of carbon, nitrogen, fluorine, and oxygen is contained in the whole of intrinsic semiconductor layer 14.

In order to manufacture the structure of the second embodiment, for example, first n-type semiconductor layer 13 is deposited while a phosphorous or arsenic-containing gas is added. Then the deposition is performed for a predetermined time while the phosphorous or arsenic-containing gas is replaced by an acetylene gas or an ethylene gas. Then the addition of the acetylene gas or ethylene gas is stopped. Then the amorphous epitaxial layer is deposited.

As a result, the diffusion prevention area containing carbon can be formed at the interface between n-type semiconductor layer 13 and intrinsic semiconductor layer 14.

Similarly, after intrinsic semiconductor layer 14 is deposited to a predetermined thickness, the deposition is performed for a predetermined time while the acetylene gas or an ethylene gas is added. Then the acetylene gas is replaced by the boron-containing gas to deposit the amorphous epitaxial layer.

As a result, the diffusion prevention area containing carbon can be formed at the interface between intrinsic semiconductor layer 14 and p-type semiconductor layer 15.

Although the epitaxial layer is formed in the amorphous state, the epitaxial layer may be formed in a polycrystalline state. When an underlying layer of a single-crystal state is formed before the epitaxial growth, the single-crystal epitaxial layer can also be formed.

The single-crystal epitaxial layer includes a small number of defects compared with the amorphous state, so that a leak current can be reduced during the reverse bias. The diffusion of the impurity into intrinsic semiconductor layer 14 from n-type semiconductor layer 13 and p-type semiconductor layer 15 can effectively be prevented.

Then electrode layer 16 is formed on p-type semiconductor layer 15, memory element (RE) 17 is formed on electrode layer 16, and electrode layer 18 is formed on memory element 17. For example, a binary or ternary metal oxide is deposited by a sputtering method to form memory element 17.

Mask layer 19 is formed on electrode layer 18. Mask layer 19 has a line pattern extended in the first direction.

Electrode layer 18, memory element 17, electrode layer 16, p-type semiconductor layer 15, intrinsic semiconductor layer 14, n-type semiconductor layer 13, electrode layer 12, and first conductive layer are sequentially etched through first-time RIE (Reactive Ion Etching) using mask layer 19 as a mask.

As a result, the first conductive layer becomes conductive line L2(i) extended in the first direction, and a side surface in the second direction of cell unit CU2 is formed on conductive line L2(i).

Then mask layer 19 is removed.

As illustrated in FIGS. 21 to 23, insulating layer (for example, oxide silicon) 20 is formed by an LPCVD method, and the trench formed on the side-surface side in the second direction of cell unit CU2 during the first-time RIE is filled with insulating layer 20.

An upper surface of insulating layer 20 is planarized such that the upper surface of insulating layer 20 and the upper surface of electrode layer 18 are disposed in a substantially identical position in the third direction.

A second conductive layer is formed on electrode layer 18 and insulating layer 20, and mask layer 21 is formed on the second conductive layer. Mask layer 21 has a line pattern extended in the second direction.

The second conductive layer, insulating layer 20, electrode layer 18, memory element 17, electrode layer 16, p-type semiconductor layer 15, intrinsic semiconductor layer 14, n-type semiconductor layer 13, and electrode layer 12 are sequentially etched through second-time RIE using mask layer 21 as a mask.

As a result, the second conductive layer becomes conductive line L3(j) extended in the second direction, and a side surface in the first direction of cell unit CU2 is formed on conductive line L2(i). That is, cell unit CU2 is formed between conductive line L2(i) and conductive line L3(j), and the cell unit CU2 comprises p-i-n diode D-pin and memory element (RE) 17 which are connected in series.

Then mask layer 21 is removed.

An insulating layer (for example, oxide silicon) is formed by the LPCVD method, and the trench formed on the side-surface side in the second direction of cell unit CU2 during the second-time RIE is filled with the insulating layer.

The upper surface of the insulating layer is planarized.

The p-i-n diode of the invention is formed through the above-described process.

The three-dimensional cross-point type memory cell array is completed by repeating the above-described process. However, except when forming the uppermost memory cell array, in the process of FIGS. 21 to 23, a stack structure (having the same structure as cell unit

CU2) constituting another cell unit on cell unit CU2 is formed between mask layer 21 and the second conductive layer constituting conductive line L3(j).

(8) Material Example

Material examples for the resistance change memory in which the p-i-n diode is used as the rectification will be described.

Each of the p-type semiconductor layer, intrinsic semiconductor layer, and n-type semiconductor layer, which are included in the p-i-n diode, is selected from the group of Si, SiGe, SiC, Ge, C, GaAs, oxide semiconductor, nitride semiconductor, carbide semiconductor, and sulfide semiconductor.

Preferably the p-type semiconductor layer (anode layer) is one of p-type Si, TiO₂, ZrO₂, InZnO_{X}, ITO, SnO₂ containing Sb, ZnO containing Al, AgSbO₃, InGaZnO₄, and ZnO.SnO₂.

Preferably the n-type semiconductor layer (cathode layer) is one of n-type Si, NiO_{X}, ZnO, Rh₂O₃, ZnO containing N, and La₂CuO₄.

The crystal states of the p-type semiconductor layer, intrinsic semiconductor layer, and n-type semiconductor layer is any one of the amorphous state, single-crystal state, and polycrystalline state.

For example, the conductive line that acts as the word line/bit line is made of W, WSi, NiSi, or CoSi. For example, the electrode layer is made of Pt, Au, Ag, TiAlN, SrRuO, Ru, RuN, Ir, Co, Ti, TiN, TaN, LaNiO, Al, PtIrOx, PtRhOx, Rh, or TaAlN. The electrode layer may simultaneously have the function as the barrier metal layer and the function as the bonding layer.

For example, the memory element is made of a binary or ternary metal oxide.

(9) Effect

When the p-i-n diode of the invention having the diffusion prevention area is used as the rectification of the resistance change memory, the thickness of the p-i-n diode can be reduced to ½ to ⅕ of that of the conventional p-i-n diode while the rectifying characteristic is maintained.

In other words, if the thickness of the p-i-n diode of the invention is equalized to that of the conventional p-i-n diode, the reverse current of the p-i-n diode of the invention to which the reverse bias is applied is at least two orders of magnitude smaller than that of the conventional p-i-n diode to which the same reverse bias is applied.

Accordingly, the reduction of the power consumption, the enhancement of the operation speed, and the ease of read can be realized in the resistance change memory.

Because the anode layer and cathode layer of the p-i-n diode are made of semiconductor, the rectifying characteristic can be controlled by changing the Fermi level of the semiconductor. Particularly, during the forward bias, the Fermi level of the n-type semiconductor layer on the side into which electrons are injected is relatively raised while the Fermi level of the p-type semiconductor layer on the side that receives electrons is relatively lowered, which allows the rectifying characteristic to be improved.

In the second embodiment, diffusion prevention areas X containing at least one of carbon, nitrogen, fluorine, and oxygen are disposed only in the end portion on the side of intrinsic semiconductor layer 14 of n-type semiconductor layer 13 in p-i-n diode D-pin and the end portion on the side of intrinsic semiconductor layer 14 of p-type semiconductor layer 15, so that the resistance of intrinsic semiconductor layer 14 can be lowered. As a result, the forward current can be gained.

3. Application Example

The resistance change memory of the embodiment has a high potential as a next-generation universal memory that replaces the current memories, such as the magnetic memory, the NAND flash memory, and the dynamic random access memory, which are used in commercially available products.

Therefore, for example, the invention can be applied to a file memory in which the data can randomly be written at high speed, a mobile terminal that can download data at high speed, a portable player that can download data at high speed, a semiconductor memory for broadcasting equipment, a drive recorder, a home video, a large-capacity buffer memory for communication, and a semiconductor memory for a security camera.

4. Conclusion

According to the invention, a p-i-n diode as the rectification of the resistance change memory can be sufficiently thinned, and can prevent a degradation of characteristic of the p-i-n diode.

The resistance change memory of the invention has a large advantage as a next-generation universal memory.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A resistance change memory comprising:
a first conductive line extending in a first direction;
a second conductive line extending in a second direction which is crossed to the first direction;
a cell unit including a memory element and a rectification connected in series between the first and second conductive lines; and
a control circuit which is connected to both of the first and second conductive lines,
wherein the control circuit controls a value of voltage which is applied to the memory element to change a resistance of the memory element reversibly between first and second values,
wherein the rectification includes a p-type semiconductor layer, an n-type semiconductor layer and an intrinsic semiconductor layer therebetween,
wherein the rectification has a first diffusion prevention area in the intrinsic semiconductor layer.

2. The memory according to claim 1,
wherein the first diffusion prevention area includes at least one of carbon, nitrogen, fluorine, and oxygen, and an atom density thereof is 1% or less.

3. The memory according to claim 2,
wherein the first diffusion prevention area includes all of the intrinsic semiconductor layer.

4. The memory according to claim 1,
wherein each of a concentration of p-type impurity in the p-type semiconductor layer and a concentration of n-type impurity in the n-type semiconductor layer is 1×10²⁰ atoms/cm³ or more.

5. The memory according to claim 1,
wherein the p-type semiconductor layer, the n-type semiconductor layer and the intrinsic semiconductor layer are epitaxial layers respectively.

6. The memory according to claim 1,
wherein each of the p-type semiconductor layer, the n-type semiconductor layer and the intrinsic semiconductor layer includes one selected from the group of Si, SiGe, SiC, Ge, C, GaAs, oxide semiconductor, nitride semiconductor, carbide semiconductor, and sulfide semiconductor.

7. The memory according to claim 1,
wherein the p-type semiconductor layer includes one selected from the group of p-type Si, TiO₂, ZrO₂, InZnO_{X}, ITO, SnO₂ containing Sb, ZnO containing Al, AgSbO₃, InGaZnO₄, and ZnO.SnO₂.

8. The memory according to claim 1,
wherein the n-type semiconductor layer includes one selected from the group of n-type Si, NiO_{X}, ZnO, Rh₂O₃, ZnO containing N, and La₂CuO₄.

9. The memory according to claim 1,
wherein each of the first and second conductive lines includes one selected from the group of W, WSi, NiSi and CoSi.

10. The memory according to claim 1, further comprising:
a first electrode between the first conductive line and the memory element;
a second electrode between the second conductive line and the rectification; and
a third electrode between the memory element and the rectification,
wherein each of the first, second and third electrodes includes one selected from the group of Pt, Au, Ag, TiAlN, SrRuO, Ru, RuN, Ir, Co, Ti, TiN, TaN, LaNiO, Al, PtIrOx, PtRhOx, Rh and TaAlN.

11. The memory according to claim 1,
wherein the rectification is a p-i-n diode.

12. The memory according to claim 1,
wherein the first diffusion prevention area is disposed to an end potion of the intrinsic semiconductor layer side of the p-type semiconductor layer.

13. The memory according to claim 1,
wherein the first diffusion prevention area is disposed to an end potion of the intrinsic semiconductor layer side of the n-type semiconductor layer.

14. The memory according to claim 12, further comprising:
a second diffusion prevention area at an end portion of the intrinsic semiconductor layer side of the n-type semiconductor layer.

15. The memory according to claim 14,
wherein the first and second diffusion prevention areas include all of the intrinsic semiconductor layer.

16. A method of manufacturing a resistance change memory comprising:
forming a memory element and a rectification on the first conductive layer;
patterning the memory element and the rectification in a line-pattern by using a mask which extends in a first direction; and
patterning the memory element and the rectification in a dot-pattern by using a mask which extends in a second direction perpendicular to the first direction;
wherein the rectification is manufactured by an amorphous epitaxial layer,
wherein the amorphous epitaxial layer is formed by flowing a phosphorous or arsenic-containing gas, next, by replacing the phosphorous or arsenic-containing gas to an acetylene gas or an ethylene gas, then, by adding a boron-containing gas to the acetylene gas or the ethylene gas.

17. The method according to claim 16,
wherein the amorphous epitaxial layer is formed by stopping the acetylene gas or the ethylene gas during a constant term, before adding a boron-containing gas to the acetylene gas or the ethylene gas.
